(19) United States
(12) Patent Application Publication
(10) Pub. No.: US 2017/0186887 A1
(43) Pub. Date: Jun. 29, 2017

(54) PV-MODULE AND METHOD FOR MAKING A SOLDER JOINT

(71) Applicant: SolarWorld Innovations GmbH, Freiberg (DE)

(72) Inventors: Harald Hahn, Dresden (DE); Christian Koch, Poehl (DE)

(21) Appl. No.: 15/361,027

(22) Filed: Nov. 24, 2016

(30) Foreign Application Priority Data
Dec. 23, 2015 (DE) 10 2015 122 785.1

(51) Int. Cl. H01L 31/02; C22C 13/00; B23K 1/00; B23K 35/26; H01L 31/0236; H01L 23/00

(52) U.S. Cl. CPC H01L 31/02008; H01L 31/02366; H01L 24/29; H01L 24/32; H01L 24/83; B23K 1/0016; B23K 35/262; C22C 13/00; H01L 2224/16245; H01L 2224/13111; H01L 2224/13113; H01L 2224/13116; H01L 2224/13109; H01L 2224/13139; H01L 2224/13118; H01L 2224/13147; H01L 2224/83815

(57) ABSTRACT

According to various embodiments, a particle containing structured solder material is provided as solder material for joining a solar cell connector with a solar cell. That is why for example, the light incident on the solder material is reflected diffusely and thus partially delivered back to the solar cell, whereby the light captured by the solar cell is increased. Less of the solar cell surface is shadowed based on the solder material or the solar cell connector.

### CROSS-REFERENCE TO RELATED APPLICATION

This application claims priority to German Patent Application Serial No. 10 2015 122 785.1, which was filed Dec. 23, 2015, and is incorporated herein by reference in its entirety.

### TECHNICAL FIELD

Various embodiments relate generally to a PV-module and a method for making a solder joint between a solar cell connector and a solar cell.

### BACKGROUND

A photovoltaic-module usually has a plurality of electrically interconnected solar cells, which are housed in a common array. For interconnecting several solar cells in such a photovoltaic-module, the so-called solar cell connectors are used, which are usually configured ribbon-shaped. For example, a solar cell connector has a copper core or a copper wire, wherein the copper core or copper wire can be coated with a solder layer (obviously by a solderable material) on all sides, wherein the solder layer enables a thermally induced connection to the solar cell. Usually, solders, i.e. solderable materials consisting of a eutectic composition are used here. Eutectic alloys usually form very fine, often lamellar microstructures when solidifying from the melt, which form a very smooth reflecting surface. Since about 4% of the usable cell area in the conventional solar modules are covered by the correspondingly used cell connectors, the light for the power generation, reflected on specular reflective (reflective mirroring) solder areas, is substantially completely lost.

To reduce these losses, which occur in conventional solar cells in which eutectic solders are used, for example, cell designs are used which relocate the contacting of the cell front-side to the non-illuminated cell rear-side [for example referred to as Emitter Wrap Through (EWT)]. For example, this can be done by means of a continuous bonding. When it is possible to direct the light reflected from the front-side solder surfaces again to the active cell surface in another way, as described in the following, such complex and cost-intensive cell designs can be avoided.

Another already used possibility to recapture the light reflected on the solder strips, consists of using the suitably structured solder strips. By means of embossing of the trench structure in the solder strips, the incident light can ideally be reflected at a very flat angle and based on a total reflection which occurs in the transition from glass to air, can again be delivered back to the module. Such a solution offers, e.g. the so-called LHS-Technique (Light Harvesting String-Technique). For example, it can be disadvantageous here that conventionally solder strips of copper should be embossed on both sides and the copper surface cannot have the optimal reflection. To improve the reflection, conventionally a thin layer of a good reflecting material, usually Silver is applied on the copper surface of such solder strips. Then, in such a case, the solder should be applied on the cell in the form of a solder paste in a separate step and for example, there is a risk that while soldering, the solder grips around the structured solder strips and again fills parts of the structure. Selectively soldered cell connectors with structured surfaces are a solution for this problem, however this in turn requires an optical positioning of soldered regions towards the solar cell, which should be realized by means of cost-intensive technology and which is not available until now. Moreover, such structured cell connectors are obviously costlier than the conventional ones, so that a part of the commercial use is consumed by increased cost of materials.

### SUMMARY

According to various embodiments, a particle containing structured solder material is provided as solder material for joining a solar cell connector with a solar cell. That is why for example, the light incident on the solder material is reflected diffusely and thus partially delivered back to the solar cell, whereby the light captured by the solar cell is increased. Less of the solar cell surface is shadowed based on the solder material or the solar cell connector.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A to 1D show a schematic top view on a section of a PV-module with several solar cells according to different exemplary embodiments (FIG. 1A), a cross-sectional view on a section of a solar cell of the PV-module from FIG. 1A (FIG. 1B), an enlarged view of a partial region of the surface of the solar cell (FIG. 1C) represented in FIG. 1B and a cross-sectional view on a section of a solar cell of the PV-module from FIG. 1A (FIG. 1D); and

FIGS. 2A to 2C respectively show a schematic cross-sectional view of a solar cell connector on a solar cell according to different exemplary embodiments;

FIG. 3 shows a schematic representation of a phase-diagram of a binary system with eutectic point according to different exemplary embodiments;

FIG. 4 shows a flow-diagram of an exemplary embodiment of a method for making a solder joint;

FIG. 5 shows a photo of solder areas on solar cell connector according to different exemplary embodiments; and

FIGS. 6A to 6C show LBIC-line scan over the solar cell connector according to different exemplary embodiments.

### DESCRIPTION

In the following detailed description, reference is made to the accompanying drawings, which form part of this description and in which specific embodiments in which the invention can be exercised are shown for illustration. It is obvious that other embodiments can be used and structural or logical modifications can be undertaken, without departing from the scope of protection of the present invention. It is obvious that the features of the different exemplary embodiments described here can be combined with each other, unless specified otherwise. Therefore, the following detailed description is not to be understood in a limited sense, and the scope of protection of the present invention is defined by the accompanying claims.

Within the scope of this description, the term “joined” is used for describing a direct as well as an indirect joint. In the figures, identical or similar elements are provided with identical reference numerals, wherever appropriate.

Within the scope of this description, the term “Front-side” or “Forward-side” is used with reference to the solar cell for describing the incidental light side of the solar cell.

Within the scope of this description, the term “Rear-side” is used with reference to the solar cell for describing the side of the solar cell opposed to the Front-side.

According to various embodiments, a particle containing structured solder material is provided as solder material for joining a solar cell connector with a solar cell. That is why for example, the light incident on the solder material is reflected diffusely and thus partially delivered back to the solar cell, whereby the light captured by the solar cell is increased. Obviously, less of the solar cell surface is shadowed based on the solder material or the solar cell connector.

The term solder material can also be referred to as soldering means, solder, solder paste, solderable joint, solder metal or the like.

A solar cell connector can also be referred to as cell connector, solder strip, solar cell connection wire, solar cell joint strips, solder strips, contact wire, contact strips or the like.

A connection of a solar cell with the correspondingly used solar cell connectors by means of a solder material can be referred to as solder joint.

The term material system can also be understood as material system, metal system, alloy system, solder material system or the like. A material system can essentially consist of two or more than two components, e.g. two or more than two metals. Thus, non-metallic impurities are ignored from consideration.

The term eutectic point can also be referred to as eutectic melting point or the like. Therefore, this term refers to the respective underlying material system. At the eutectic point, the components have weight percentages, at which a uniform and minimum melting point appears. The weight percentages at the eutectic point are referred to here as eutectic weight percentages or eutectic proportions. While cooling a solder material from the melt, this solidifies as a solid phase with eutectic composition at the eutectic point, which can be referred to as eutectic phase. If the melt of the solder material has a eutectic composition or if the melt of the solder materials consists of components with eutectic weight percentages, this solidifies at the eutectic point essentially completely as eutectic phase.

The term non-eutectic solder material is used here with the meaning that the melt of the solder material has a chemical composition, which is essentially different (e.g. at least 20% by weight) from the eutectic composition.

If the melt of the solder material has a non-eutectic composition or if the melt of the solder material consists of components with non-eutectic weight percentages, this solidifies with at least one additional phase besides the eutectic phase. Thereby, besides the eutectic phase, the solidified non-eutectic solder material has, for example, at least one phase which is rich in one of the components.

Here, a component is also referred to as metallic element, alloying element or metal. The components can have customary unavoidable impurities, which are ignored from consideration.

The term high-melting components herein is used here with the meaning that the component has a melting temperature of at least 400° C.

The term diffuse reflection is used here with the meaning that the incident light is not reflecting, but scattered in different directions essentially according to the Lambert's Law of Reflection. A diffuse reflection of a light can occur on a surface if the roughness of the surface is of the order of the (or greater than the) wavelengths of the incident light. A diffusely reflecting surface is used here with the meaning that the surface produces a diffuse reflection of the incident light. Obviously, thus the term “diffuse reflecting surface” is used here with the meaning that the surface has a roughness, which is of the order of the (or greater than the) wavelength of the visible light. For example, the surface can have an average roughness (Ra) of at least 150 nm, at least 300 nm or at least 500 nm, e.g. in a range of approximately 150 nm to approximately 5 μm or in a range of approximately 300 nm to approximately 3 μm.

For example, different embodiments are based on using a solder material for a solar cell connector, which forms a rough surface after solidification, and thus also forms a diffusely reflecting surface based on the rough surface. For example, for this purpose, a predefined chemical composition of the solder material is used which is different from the eutectic composition of the material system corresponding to the components of the solder material.

According to different embodiments, a PV-module can have several crystalline solar cells, which are electrically connected to solar cell connectors, wherein the solar cell connectors have a metallic carrier and a solder material applied on the carrier. The solder material has at least one first component and a second component, which do not mix in solid state and therefore form a eutectic system. In accordance with various embodiments, the proportion of one of the components differs by at least 5% by weight from the eutectic composition of the system. The solar cell connector has a rough diffusely reflecting surface.

In an embodiment, one of the components can be a high-melting component, for example -Zinc, Copper or Silver.

In an embodiment, the proportion of one of the components can differ by at least 20% by weight from the eutectic composition of the system.

Further, the solder material can have one or several more components with an total proportion up to 20% by weight of all the components.

In an exemplary embodiment, the first component can have Tin, Bismuth, Lead or Indium.

In another exemplary embodiment, the second component can have Tin, Lead, Bismuth, Silver, Indium, Zinc, Cadmium, Antimony or Copper. Furthermore, the solder material can have a layer-thickness in a range of about 5 μm to about 100 μm. The solder material can have particles of a component with a size of at least about 300 nm. For example, the particles can have a size in a range of 300 nm to 50 μm. In addition, the particles can have a size corresponding to half the layer thickness of the solder material, for example in a range of about 2.5 μm to about 50 μm.

In another exemplary embodiment, the solar cell connectors can have a surface roughness of at least 150 nm. For example, the surface roughness can be 500 nm or several μm. For example, the surface roughness can be up to approximately 50 μm. Furthermore, at least 5% (for example 10%, 25%) of the light incident perpendicular to a solar cell connector can be reflected at an angle of 40° or higher (for example 50°, 60° or 70°).

Further according to different embodiments, a method is provided for making a solder joint between a solar cell connector and a solar cell. The method can have the following steps: Applying a solar cell connector on the solar cell, wherein the solar cell connector has a metallic carrier and a solder material differing from the eutectic composition (so-called non-eutectic) applied on the carrier, which has at least one first component and a second component, wherein the proportion of one of the first and the second component can differ by at least 5% by weight from the eutectic point; heating the solder material; and cooling the solder material, so that a metallic bond is formed between the solar cell connector and the solar cell with a rough diffusely reflecting surface.

In an embodiment, the one of the first component and the second component can be a high-melting component, for example Zinc, Copper or Silver. If the high-melting component has a melting temperature above 400° C., the difference of the proportion of the high-melting component can be of at least 10% by weight from the eutectic point adequate to achieve the effect of formation of the particles and thereby scattering of light during cooling. If the high-melting component has a melting temperature above 900° C., the difference of the proportion of the high-melting component can be at least 5% by weight from the eutectic point adequate to achieve the effect according to various embodiments.

In an embodiment, the proportion of at least one of the components can differ by at least by 20% by weight from the eutectic composition of the system.

In an exemplary embodiment, the solder material can be heated to a temperature above the liquidus temperature of this solder material.

In another exemplary embodiment, the solder material can be heated to a temperature below the liquidus temperature of this solder material. The solder material can also be heated between the liquidus temperature and the solidus temperature. Therefore, the surplus component cannot be completely fused and there are small particles remaining in the non-eutectic composition, which subsequently function as condensation nuclei for the formation of still larger and better light-scattering particles and produce a high surface roughness.

In addition, the solder material can be heated in a locally confined region on the solar cell connectors. Furthermore, this local region can be moved with a speed between 0.1 cm/s and 10 cm/s along the solar cell connector. Further, the temperature in the local region can be between 50° C. and 300° C. above the liquidus temperature of the solder material. Therefore, the heat input can be affected by contact brazing unit, spotlight (halogen, infrared or other lamps), Laser or hot-air unit.

Further, the rough diffusely reflecting surface can be produced by particles of a component. In the particles, the particle size can be controlled by means of controlled (e.g. accelerated or decelerated) cooling. Therefore, the cooling duration can be controlled such that the particles have a minimum size of about 300 nm on the surface of the solar cell connectors.

Furthermore, the solar cell connectors can be pressed on one or more solar cells by means of a retaining device, during the cooling of the solder material.

According to different embodiments, a solder material for connecting a metallic carrier with a solar cell can consist of at least 80% by weight of a first element and a second element, wherein both the elements define a binary system with a eutectic point and eutectic weight percentages; wherein the weight percentage of the first element in the solder material and the weight percentage of the second element in the solder material each differs by at least 20% by weight from the respective eutectic weight percentages.

According to a first exemplary embodiment, a PV-module can have several solar cells, which are electrically connected to the solar cell connectors, wherein the solar cell connectors have the following: a metallic carrier; and a solder material applied on the carrier, wherein the solder material consists of at least 80% by weight of a first element and a second element, wherein both the elements define a eutectic point with eutectic weight percentages; wherein the weight percentage of at least one element in the solder material differs by at least 20% from the respective eutectic weight percentage.

According to a second exemplary embodiment, the PV-module according to the first exemplary embodiment can be configured such that the solder materials have further elements with a weight percentage up to 20% of the total weight of all the components.

According to a third exemplary embodiment, the PV-module according to the first or second exemplary embodiment can be configured such that the first element has a larger weight percentage than the second element and is Tin, Bismuth, Lead or Indium.

According to a fourth exemplary embodiment, the PV-module according to the first to third exemplary embodiments can be configured such that the second element has a smaller weight percentage than the first element and is Tin, Lead, Bismuth, Silver, Indium, Zinc or Copper. It should be understood that the second element is different from the first element.

According to a fifth exemplary embodiment, the PV-module according to the first to fourth exemplary embodiments can be configured such that the solder material is applied as a layer and has a coating thickness in a range of 5 μm to 100 μm.

According to a sixth exemplary embodiment, the PV-module according to the first to fifth exemplary embodiments can be configured such that the solder material has particles with an average particle size each of at least 300 nm and that the particles essentially consist of one of the elements of the solder mixture.

According to a seventh exemplary embodiment, the PV-module according to the first to sixth exemplary embodiments can be configured such that the particles have an average particle size (e.g. an average geometric equivalent diameter) in a range of 300 nm to 50 μm.

According to an eighth exemplary embodiment, the PV-module according to the first to seventh exemplary embodiments can be configured such that the solar cell connectors have a surface roughness of at least 150 nm.

According to a ninth exemplary embodiment, the PV-module according to the first to eighth exemplary embodiments can be configured such that at least 5% of the light incident perpendicular to a solar cell connector is reflected at an angle of 40° or larger, wherein the angle is made with reference to the surface normal of the cell connector.

According to a tenth exemplary embodiment, a method for connecting a solar cell connector with a solar cell can have the following steps: Applying a solar cell connector on the solar cell, wherein the solar cell connector has a metallic carrier and a solder material applied on the carrier, wherein the solder material consist of at least 80% by weight of a first element and a second element (obviously, the elements are not the same), wherein the both elements define a eutectic point with eutectic weight percentages; and wherein the weight percentage of the first element in the solder material and the weight percentage of the second element in the solder material each differs by at least 20% from the respective eutectic weight percentage; heating the solder material; and cooling the solder material, wherein the solar cell connector is integrally bonded with the solar cell, wherein the solder material has a rough diffusely reflecting surface after cooling.

According to an eleventh exemplary embodiment, the PV-module according to the tenth exemplary embodiment can be configured such that the solder material is heated to a temperature below the liquidus temperature of this solder material.

According to a twelfth exemplary embodiment, the PV-module according to the tenth or eleventh exemplary embodiment can be configured such that the solder material is heated in a locally confined region on the solar cell connector and that this local region is moved along the solar cell connector with a speed between 0.1 cm/s and 10 cm/s.

According to a thirteenth exemplary embodiment, the PV-module according to the tenth to twelfth exemplary embodiments can be configured such that the temperature in the local region is between 50° C. and 300° C. above the liquidus temperature of the solder material.

According to a fourteenth exemplary embodiment, the PV-module according to the tenth to thirteenth exemplary embodiments can be configured such that the heat input is affected by contact brazing unit, spotlight (halogen, infrared or other lamps), Laser or hot-air unit.

According to a fifteenth exemplary embodiment, the PV-module according to the tenth to fourteenth exemplary embodiments can be configured such that the rough diffusely reflecting surface is essentially produced by particles of a component of the solder material, wherein the particle size is controlled by a controlled cooling.

According to a sixteenth exemplary embodiment, the PV-module according to the tenth to fifteenth exemplary embodiments can be configured such that the cooling duration is controlled such that the particles on the surface of the solar cell connector have a minimum size of about 300 nm.

According to a seventeenth exemplary embodiment, the PV-module according to the tenth to sixteenth exemplary embodiment is configured such that during the cooling of the solder material, the solar cell connector is accelerated by means of a retaining device and pressed on one or more solar cells.

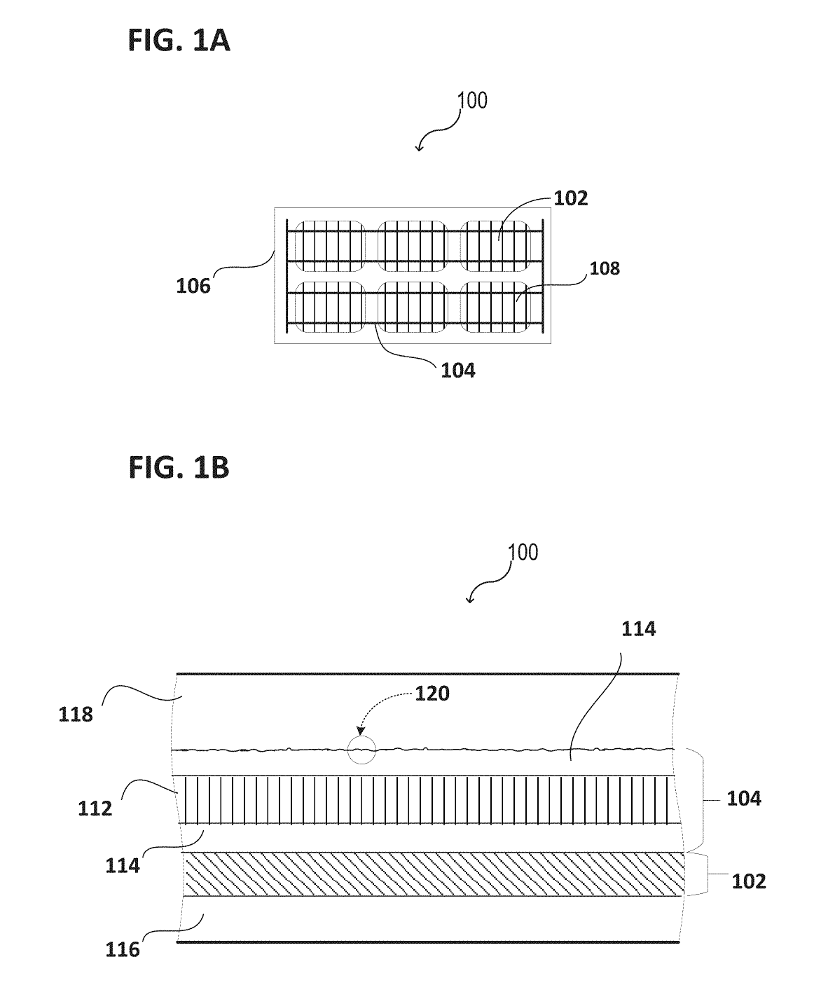

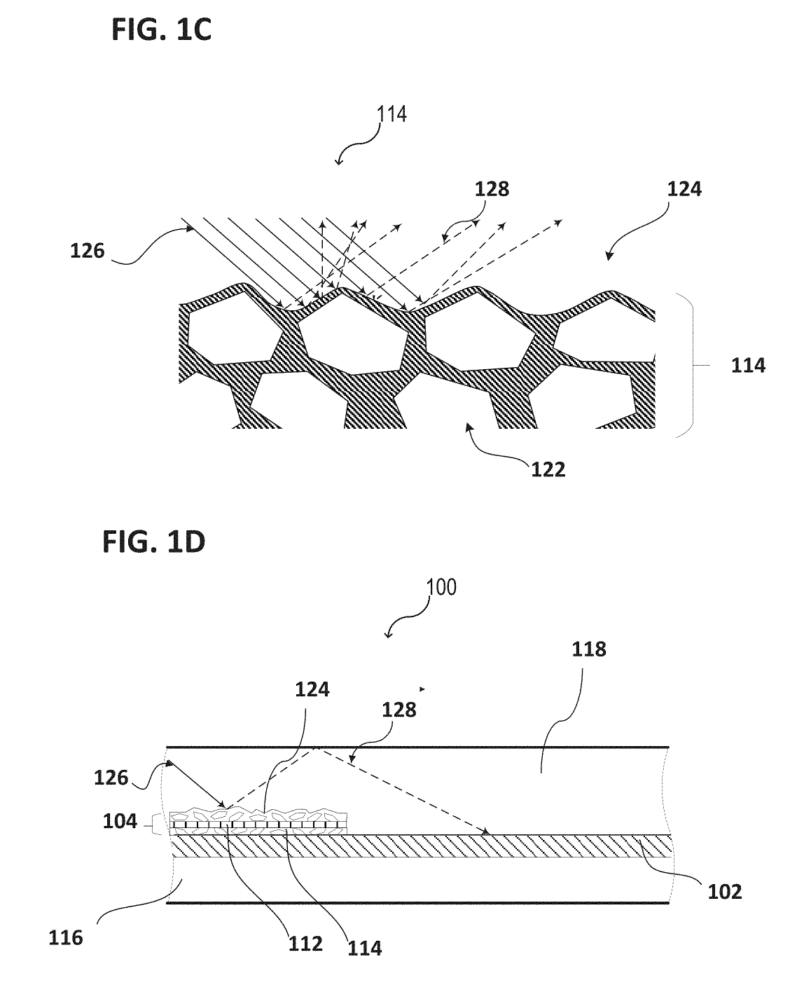

FIG. 1A illustrates a photovoltaic-module 100 (abbreviated as PV-module 100). The module 100 has several solar cells 102, which are electrically interconnected by means of solar cell connectors 104. The PV-module 100 can be surrounded by a frame 106, for example made of Aluminum. Further, the several solar cells and the solar cell connectors 104 can be laminated.

The several solar cells 102 can be interconnected in a series connection or a parallel connection or in any combination of interconnection of series connection and parallel connection by means of electrically conducting solar cell connectors 104.

The solar cells 102 can be a crystalline material (e.g. crystalline Silicon), for example monocrystalline, or polycrystalline.

The solar cells 102 have one or more electric wires 108, e.g. referred to as finger or Busbar on the front-side for collecting the electric current generated by means of the respective solar cell 102.

The solar cell connectors 104 can have a metallic carrier and a solder material, wherein the solder material has a non-eutectic composition such that the solidified solder material has a rough surface.

FIG. 1B shows a schematic cross-sectional view of the PV-module 100. Therefore, the solar cell connector 104 is disposed on the front-side of the solar cell 102. The solar cell 102 can be covered on the rear-side with a composite plastic film 116, for example polyvinyl fluoride and polyester or a glass pane. The solar cell 102 and the solar cell connector 104 can be covered on the front-side by a glass pane 118. Further, the solar cell 102 and the solar cell connector 104 can be encapsulated by means of an encapsulation layer (not represented). The solar cell connector 104 has a metallic carrier 112 and a non-eutectic solder material 114 applied on the metallic carrier 112. Therefore, a portion of the solder material 114 makes contact (e.g. the electrical contact and/or the physical contact) between the metallic carrier 112 and the front-side of the solar cell 102.

The metallic carrier 112 can have at least one metal or or consist thereof, for example Copper, Aluminum, Gold, Platinum, Silver, Lead, Tin, Molybdenum, Iron, Nickel, Cobalt, Zinc, Titanium, Tungsten; or an alloy of several of the aforementioned metals. The metallic carrier 112 can have a predefined wire cross-section as electrical conductor, e.g. in a range of approximately 0.1 mm2 to approximately 15 mm². The shape of the wire cross-section can be, for example square, rectangular, triangular or any appropriate n-angular, or even circular or oval. If the metallic carrier 112 is rectangular (e.g. if a metal strip is used), this can have a height in a range of approximately 0.1 mm to approximately 3 mm. Further, the metallic carrier 112 can have a width in a range of approximately 0.1 mm to approximately 5 mm. If the metallic carrier 112 is circular (e.g. if a wire is used), this can have a diameter in a range of approximately 0.1 mm to approximately 5 mm.

The metallic carrier 112 is or can be completely or partially coated with, for example, the non-eutectic solder material 114. The solder material 114 can have a layer thickness in a range of approximately 5 μm to 100 μm, for example in a range of approximately 20 μm to 80 μm, for example in a range of approximately 40 μm to 60 μm. The non-eutectic solder material 114 can be an alloy or the like.

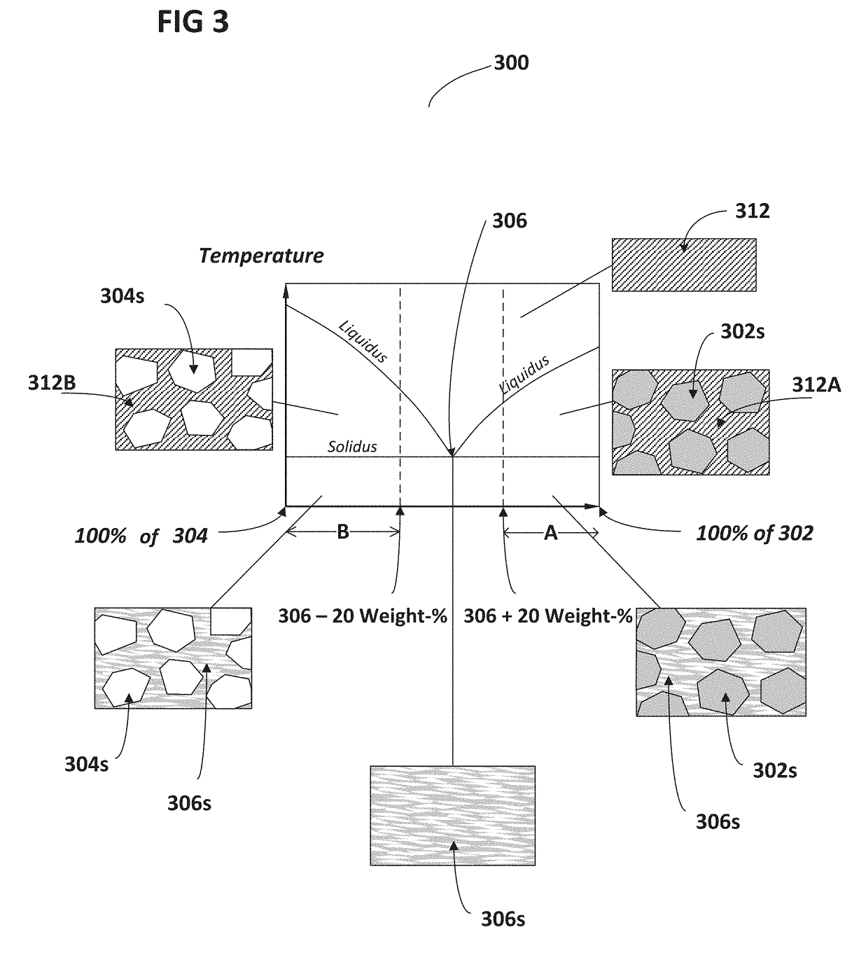

In different exemplary embodiments, the solder material 114 can have at least a first component and a second component (for example exactly or more than a first and a second component) (compare for example, the two components 302, 304 in FIG. 3).

In different exemplary embodiments, the solder material 114 has a first component, a second component and further components, wherein the weight percentage of further components can be up to 20% by weight with respect to the total components. For Example, the first component can be or have Tin, Bismuth, Lead or Indium. For example, the second component can be or have Tin, Lead, Bismuth, Silver, Indium, Zinc or Copper. The first component, the second component and the further components form a multicomponent system and define a eutectic point with eutectic weight percentages, wherein the weight percentage of at least one of the components obviously differs (for example at least 20% by weight) from the eutectic composition. It is obvious that the first component, the second component and the further components are different from each other.

In an exemplary embodiment, the solder material 114 consists of a first component and a second component (compare for example, the two components 302, 304 in FIG. 3). For example, the two components define a binary system, and define a eutectic point with eutectic weight percentages, also referred to as eutectic composition. In the non-eutectic solder material 114, the the weight percentage of the first component and the weight percentage of the second component differ from the respective weight percentages at the eutectic point of the binary system, by at least 20% by weight, for example by at least 275 by weight, for example by at least 43% by weight. In the solder material, the weight percentage with respect to a component is understood such that it means the total weight percentage of a component in the non-eutectic solder material 114, for example the sum of the weight percentages of a component in solid form in the particles and in eutectic phase in the solder material 114 or for example the sum of the weight percentages of a component in the melt and in the solid particles present in the melt.

In another exemplary embodiment, the solder material 114 consists of a first component, a second component and at least one third component. The at least third component is different from the first component and is also different from the second component, wherein the weight percentage of the at least one third component can be up to 20% by weight with respect to the total components. The first component and the second component represent the main constituents of the solder material 114. For example, the non-eutectic solder material 114 can consist of up to at least 80% by weight of the first component and the second component, wherein none of the two components has less than 10% by weight. For example, the non-eutectic solder material 114 can consist of at least up to 95% by weight, for example up to at least 98% by weight of the first component and the second component. The first component and the second component can be referred to as main components. The at least one third component is different from the first and the second component. For example, the at least one third component can be Zinc, Silver, Copper, Germanium, Antimony or Aluminum. The at least one third component can further have a weight percentage up to 20% by weight, for example up to 15.5% by weight, for example up to 8% by weight, for example up to 2% by weight, for example up to 1% by weight, for example up to 0.5% by weight.

For example, the at least one third component can be added—by alloying, addition in the fluid state etc.—to the first and the second components. For example, the at least one third component forms a ternary system along with the first component and the second component. The sum of the weight concentration of the first, the second and the at least third components adds to 100% by weight, at least with respect to the metallic constituents. In this exemplary embodiment, the weight percentages of the first component and the second component are selected as main components such that they differ by at least 20% by weight, for example by at least 27% by weight, for example by at least 43% by weight, from the respective weight percentages at the eutectic point of the binary system, which form the main components.

Further, the non-eutectic solder material has a relatively high solidus temperature. The chemical composition of the solder material is selected such that the solidus temperature of the solder material is above usual lamination temperatures (e.g. in a range of approximately 100° C. to approximately 300° C.) for laminating the solar cell 102. Thereby, because the solidus temperature of the solder material is above the respective lamination temperature, the formed structures of the solder material remain preserved during the lamination.

FIG. 1C shows a schematic detail representation of the solder material 114 according to different exemplary embodiments. Because the solder material 114 is non-eutectic, the solder material 114 is structured during the soldering process, so that a microstructure is formed with particles 122. The particles 122 can have an average particle size each of at least 300 nm, for example in a range of 300 nm to 50 μm, for example in a range of 1 μm to 20 μm. The particles 122 in the solder material 114 do not form any reflecting composite surfaces, the surface normals of which have—statistically distributed—all possible directions. This microstructure results in a non-smooth-reflecting rough surface 124 of the solder material 114 or of the solar cell connectors 104 having solder material. The surface 124 can have an average roughness (Ra) of at least approximately 150 nm. The roughness can be determined by usual method, for example by means of contact technologies, for example simple portable instruments with skid button and high-grade stationary surface profiler with free tracer, or for example by means of contactless systems, for example of the confocal microscopy. Further, the roughness of a surface can be determined by means of Atomic Force Microscopy (AFM). The roughness of the surface 124 is such that it is greater in comparison to the wavelengths of the incident light 126. Thus, the surface 124 imparts a diffuse reflection of the incident light 126, wherein the incident light 126 is scattered in different directions 128. The aim is to allow the cell connector to integrally scatter back at least 5% of the incident light at an angle of more than 40° , wherein the angle is formed with respect to the surface normal of the cell connector.

FIG. 1D shows a schematic cross-sectional view of the PV-module 100 according to different exemplary embodiments. Because the surface 124 of the solar cell connector 104 is rough and the incident light 126 is diffusely reflected on the surface 124, the light 128 is deliver back by reflection in transition from glass 118 (or another transparent medium above the solar cell 102) to air (or to the surrounding) into the photovoltaic-module on the solar cell 102, whereby the efficiency of the PV-module 100 is increased.

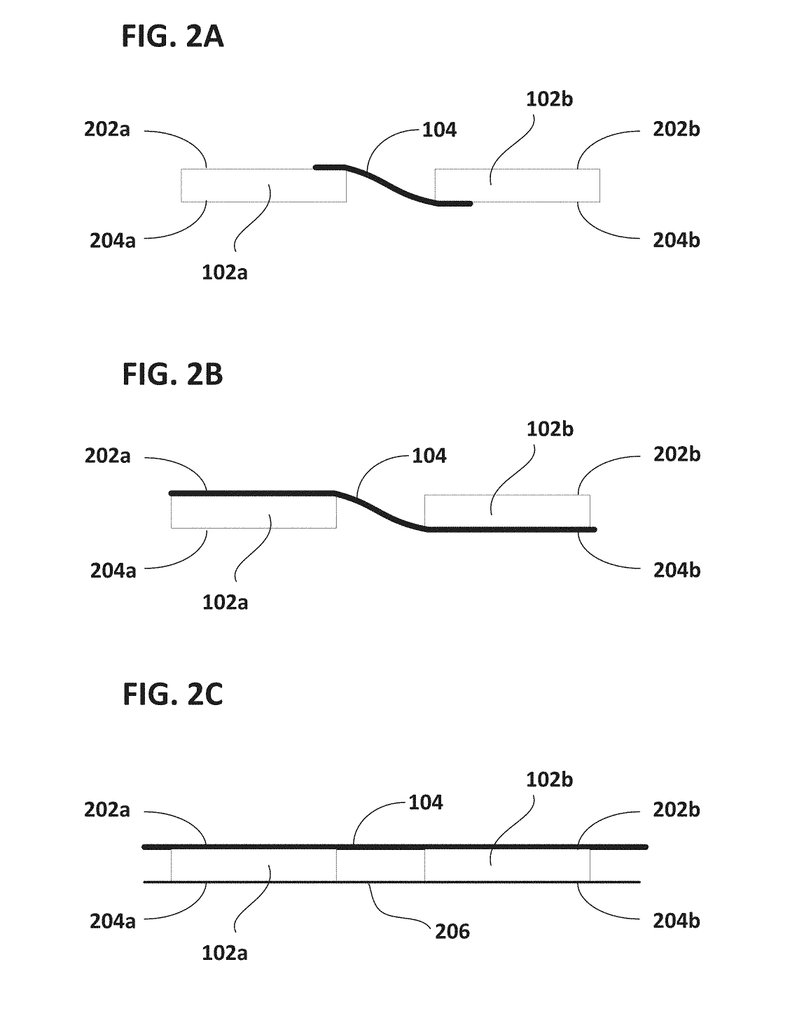

As illustrated in FIG. 2A, for interconnecting two solar cells, the front-side 202a of a first solar cell 102a can be connected to the rear-side 204b of a second (e.g. adjacent) solar cell 102b by means of a solar cell connector 104.

The solar cell connector 104 can be configured in different geometric shapes, such as a shape circular in cross-section (for example circular), an oval shape, a triangular shape, a rectangular shape (for example a square shape) or any other appropriate polygonal shape.

The solar cell connector 104 can be integrally bonded by means of soldering on at least one position, also referred to as contact on each of the solar cell of the PV-module 100. The contacts can be on the front-side of the solar cell, for example on the Busbars. Any appropriate metallization can be used as rear-side contact on the rear-side of the solar cell.

As illustrated in FIG. 2B, the solar cell connector 104 can extend along the front-side 202a of the first solar cell 102a and along the rear-side 204b of the second solar cell 102b. The solar cell connectors 104 can have a sufficient length in this exemplary embodiment.

FIG. 2C illustrates another exemplary embodiment for interconnecting two solar cells 102, wherein a first solar cell connector 104 can connect the front-sides 202a, 202b of the two solar cells 102 and wherein a second solar cell connector 206 can connect the rear-sides 204a, 204b of the two solar cells 102. The solar cell connectors 206 can be configured on the rear-side 204a, 204b of the solar cells 102 exactly as in the solar cell connectors 104 on the front-side 202a, 202b of the solar cells 102 described herein. Alternatively, the solar cell connectors 206 can be configured differently on the rear-side 204a, 204b of the solar cells 102.

FIG. 3 shows a schematic representation of a phase diagram of a binary system with complete insolubility in the solid state 300 according to different exemplary embodiments.

As FIG. 3 illustrates, the solder material 114 consists of a first component 302 and a second component 304, namely two metals, wherein the first metal 302 and the second metal 304 form a binary system 300. Thus, the binary system defines a eutectic point 306 with eutectic composition, which has eutectic weight percentages of first metal 302 and second metal 304. During cooling of the eutectic composite melt of eutectic weight percentages, a fine monocrystalline common lamellar solid structure of the first component 302 and the second component 304, also referred to as a solid eutectic phase 306s develops at the eutectic point 306. These solders with eutectic composition mostly have a very glossy, reflecting surface.

If the proportions of the first component 302 and the second component differ from the eutectic proportions, with increasing deviation from the eutectic point 306 at increasingly high temperature (liquidus temperature), crystals also referred to as particles 122 of the respective surplus components, prematurely start to form in the melt 312. With increasing growth, the remaining melt 312A/312B of the surplus component depletes, until a eutectic composition has set in at the so-called solidus temperature in the remaining melt 312A/312B. With further cooling, the fine crystalline structure of the solid eutectic phase 306s begins to form again between the rough particles. The resulting solder surface 124 has an increased roughness by the formation of the rough particles 122. This is manifested by the appearance of a matt, hardly reflecting surface 124.

In an exemplary embodiment, the first component 302 can be Tin, Bismuth, Lead or Indium. The second component 304 is different from the first component 302 and for example can be Lead, Bismuth, Silver, Indium, Zinc or Copper.

In the non-eutectic solder material 114, the weight percentage of the first component 302 and the weight percentage of the second component 304 differ from the respective weight percentages at the eutectic point 306 of the binary system by at least 20% by weight, for example by at least 27% by weight, for example by at least 43% by weight. In the solder material 114, the weight percentage with respect to a component is understood such that it means the total weight percentage of a component in the non-eutectic solder material 114, for example the sum of the weight percentages of a component in solid form in particles 122 and in the solid eutectic phase 306s in the solder material 114 or for example, the sum of the weight percentages of a component in the melt 312 and in the solid particles 122 mixed in the melt 312.

In an exemplary embodiment, the first component 302 in the non-eutectic solder material 114 can have a greater weight percentage than the second component 304 (section A). If the solder material is between the liquidus temperature and above the solidus temperature of the solder material 114, the solder material 114 can have pure particles 302s from the first component 302 and melt 312A from the first component 302 and the second component 304. Below the solidus temperature of the solder material, the solder material 114 can have pure particles 122 from the first component 302s and the solid eutectic phase 306s.

In an exemplary embodiment, the first component 302 in the non-eutectic solder material 114 can have a greater weight percentage than the second component 304 (section B). If the solder material is between the liquidus temperature and above the solidus temperature of the solder material 114, the solder material 114 can have pure particles 304s from the second component 304 and melt 312A from the first component 302 and the second component 304. Below the solidus temperature of the solder material, the solder material 114 can have pure particles 122 from the second component 304s and the solid eutectic phase 306s.

According to another exemplary embodiment, the first component 302 and the second component 304 of the solder material 114 can form a binary system with limited solubility in the solid state. The first component 302 and the second component 304 define a eutectic point 306 in the same way as in the binary system with complete insolubility in the solid state. In the same way, the weight percentage of the first component 302 and the weight percentage of the second component 304 differ by at least 20% by weight from the respective weight percentages at the eutectic point 306 of the binary system.

In an exemplary embodiment, the first component 302 in the non-eutectic solder material 114 can have a greater weight percentage than the second component 304. Below the solidus temperature of the solder material, the solder material 114 can have particles 122 essentially from the first component 302s and the solid eutectic phase 306s. The particles 122 can consist of at least 80% by weight of the first component 302s and maximum 20% by weight of the second component 304s, for example at least 90% by weight of the first component 302s and maximum 10% by weight of the second component 304s, for example at least 95% by weight of the first component 302s and maximum 5% by weight of the second component 304s.

In an exemplary embodiment, the second component 304 in the non-eutectic solder material 114 can have a greater weight percentage than the first component 302. Below the solidus temperature of the solder material, the solder material 114 can have particles 122 essentially from the second component 302s and the solid eutectic phase 306s. The particles 122 can consist of at least 80% by weight of the second component 304s and maximum 20% by weight of the first component 302s, for example minimum 90% by weight of the second component 304s and maximum 10% by weight of the first component 302s, for example minimum 95% by weight of the second component 304s and maximum 55 by weight of the first component 302s.

According to another exemplary embodiment, the non-eutectic solder material 114 can also be a ternary system. The three components form a ternary system, wherein the components have a complete or partially insolubility in the solid state. In this case, the solder material 114 has a first component 302, a second component 304 and a third component 305, wherein the first component 302 and the second component 304 represent the main constituents of the solder material 114. The sum of the metallic weight percentages of the three components is 100% by weight. For example, the non-eutectic solder material 114 can consist of at least 90% by weight of the first component 302 and the second component 304, wherein none of the two components 302 and 304 has less than 10% by weight percentage, for example at least 95% by weight, for example at least 98% by weight. The first component 302 and the second component 304 can be referred to as main components.

The third component 305 is different from the first 302 and the second 304 components. For example, the third component 305 can be Zinc, Silver, Copper, Germanium, Antimony or Aluminum. The third component 305 can further have a weight percentage up to 20% by weight, for example up to 15.5% by weight, for example up to 9% by weight, for example up to 2% by weight, for example up to 1% by weight, for example up to 0.5% by weight. The weight percentage of the first component 302 and the weight percentage of the second component 304 in the ternary system differs from the respective weight percentages at the eutectic point 306 of the binary system which form the main components, by at least 20% by weight, for example by at least 27% by weight, for example by at least 43% by weight.

During solidification of the solder material 114, first pure crystals of the surplus component are eliminated. In case, the two other components available in the melt are not present in the ternary eutectic ratio, a binary eutectic is eliminated, until the composition of the ternary eutectic is reached in the melt and this crystallises. In this way, the solder material 114 can have a first type of particles from a component available surplus in the melt and a second type of particles from the two other components.

According to an exemplary embodiment, the solder material 114 can have particles 122 essentially from a component, wherein the average particle size is above the wavelengths of the incoming light. For example, the solder material 114 can have particles 122 with an average particle size of at least 300 nm, for example with an average particle size each of at least 300 nm, for example each of at least 700 nm, for example each of at least 1 μm. For example, the solder material 114 can have particles 122 with an average particle size which corresponds to half the layer thickness of the solder material, for example up to 3 μm, for example up to 50 μm.

Because the particles 122 assume dimensions above the respective wavelengths of light, the light diffusely reflected on the surface is partially reflected at the total reflection angle of the air-glass transition, remains trapped in the PV-module and is delivered bacl for power generation.

For example, the solder material can be an alloy of Tin and Lead (SnPb). The alloy SnPb defines a binary system, wherein the eutectic composition SnPb at the eutectic point has weight percentages of Tin and Lead of 63% by weight or 37% by weight. For example, the non-eutectic solder material of SnPb, which differs by at least 20% by weight from the eutectic composition, has a weight percentage of Tin of less than 43% by weight and a weight percentage of Lead of at least 57% by weight. For example, the non-eutectic solder material of SnPb which differs by at least 20% by weight from the eutectic composition, has a weight percentage of Tin of at least 83% by weight and a weight percentage of Lead of less than 17% by weight.

For example, the solder material can be an alloy of Tin and Bismuth (SnBi). The alloy SnBi defines a binary system, wherein the eutectic composition SnBi at the eutectic point has weight percentages of Tin and Lead of 42% by weight or 58% by weight. For example, the non-eutectic solder material of SnBi which differs by at least 20% by weight from the eutectic composition, has a weight percentage of Tin of less than 22% by weight and a weight percentage of Bismuth of at least 78% by weight. For example, the non-eutectic solder material of SnBi which differs by at least 20% by weight from the eutectic composition, has a weight percentage of Tin of at least 62% by weight and a weight percentage of Bismuth of less than 38% by weight.

For example, the solder material can be an alloy of Tin and Copper (SnCu). The alloy SnCu defines a binary system, wherein the eutectic composition SnCu at the eutectic point has weight percentages of Tin and Copper of 99% by weight or 1% by weight. For example, the non-eutectic solder material of SnCu which differs by at least 5% by weight from the eutectic composition, has a weight percentage of Tin of less than 94% by weight and a weight percentage of Copper of more than 6% by weight.

For example, the solder material can be an alloy of Tin and Indium (SnIn). The alloy SnIn defines a binary system, wherein the eutectic composition SnIn at the eutectic point has weight percentages of Tin and Indium of 48% by weight or 52% by weight. For example, the non-eutectic solder material of SnIn which differs by at least 20% by weight from the eutectic composition, has a weight percentage of Tin of less than 28% by weight and a weight percentage of Indium of at least 72% by weight. For example, the non-eutectic solder material which differs by at least 20% by weight from the eutectic composition of SnIn has a weight percentage of Tin of at least 68% by weight and a weight percentage of Indium of less than 32% by weight.

For example, the solder material can be an alloy of Tin and Zinc (SnZn). The alloy SnZn defines the binary system, wherein the eutectic composition SnZn at the eutectic point has a weight percentage of Tin and Zinc of 91% by weight or 9% by weight. For example, the non-eutectic solder material of SnZn which differs by at least 10% by weight from the eutectic composition, has a weight percentage of Tin of less than 81% by weight and a weight percentage of Zinc of more than 19% by weight.

For example, the solder material can be an alloy of tin and Silver (SnAg). The alloy SnAg defines a binary system, wherein the eutectic composition SnAg at the eutectic point has a weight percentage of Tin and Silver of 96.5% by weight or 3.5% by weight. For example, the non-eutectic solder material of SnAg which differs by at least 20% by weight from the eutectic composition, has a weight percentage of Tin of less than 76.5% by weight and a weight percentage of SilVer of more than 23.5% by weight.

For example, the solder material can be an alloy of Tin, Lead and Silver (SnPbAg). The alloy SnPbAg defines a ternary system. For example, the weight percentage of Silver at 2% by weight and eutectic weight percentage of Tin and Lead are at 62% by weight or 36% by weight at the eutectic point. For example, the non-eutectic solder material of SnPbAg which differs by at least 20% by weight from the eutectic composition of the binary system SnPb, has a weight percentage of Tin of less than 42% by weight and a weight percentage of Lead of at least 56% by weight. For example, the non-eutectic solder material of SnPbAg which differs by at least 20% by weight from the eutectic composition of the binary system SnPb, has a weight percentage of Tin of at least 82% by weight and a weight percentage of Lead of less than 16% by weight.

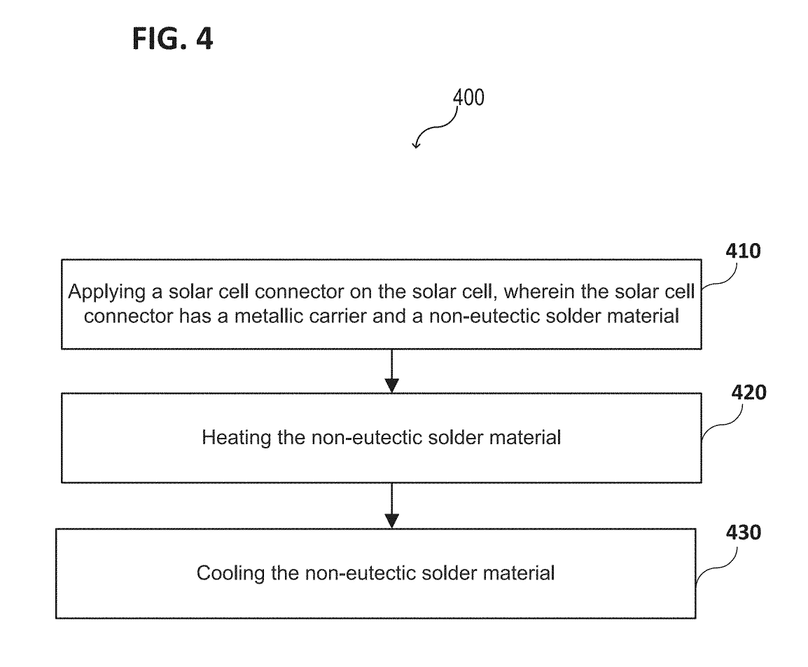

FIG. 4 illustrates a flow-diagram for a method 400 for making a solder joint according to different exemplary embodiments. Therefore, the method 400 can be carried out in corresponding to the configuration of the PV-module 100 or solder material 114 described here.

In different exemplary embodiments, a method 400 is provided for making a solder joint. The method has: Applying 402 a solar cell connector on the solar cell, wherein the solar cell connector has a metallic carrier and a non-eutectic solder material applied on the carrier; heating 404 the solder material 114; and cooling 406 the solder material. The non-eutectic solder material has a first component and a second component, wherein the weight percentage of the first component and the second component differs by at least 5% from the weight percentages of the eutectic composition. The solder material is configured such that during cooling, an integral joint, also referred to a solder joint is formed between the solar cell connector and the solar cell, wherein the solder material has a rough diffusely reflecting surface 124.

In a configuration, one of the first and second components can be a high-melting component, for example Zinc, Copper or Silver.

In an embodiment, the proportion of at least one of the first and second components differs by at least 20% by weight from the eutectic composition of the system. Further, the proportions of the first and the second components differ by at least 20% by weight from the eutectic composition of the system.

In different exemplary embodiments, applying 402 the solar cell connector on the solar cell on contacts takes place on the front-side of the solar cell, for example on the Busbars. In different exemplary embodiments, applying 402 the solar cell connector on the solar cell on contacts takes place on the rear-side of the solar cell.

In different exemplary embodiments, heating 604 of the non-eutectic solder material takes place to a temperature above the liquidus temperature of the non-eutectic solder material. In other words: the non-eutectic solder material can be heated to a temperature, at which it is in the form of a melt.

In different exemplary embodiments, heating 404 of the solder material can take place in a locally confined region on the solar cell connector. In different exemplary embodiments, the local region can be moved along solar cell connector with a speed between 0.1 cm/s and 10 cm/s. The temperature in the local region can be between 50° C. and 300° C. above the liquidus temperature of the solder material, for example between 100° C. and 200° C. above the liquidus temperature of the solder material.

Furthermore, heating 404 of the solder material can be affected through heat input by contact brazing unit, spotlight, for example halogen, infrared or other lamps, Laser or hot-air unit.

In different exemplary embodiments, cooling 406 of the non-eutectic solder material is done such that the rough diffusely reflecting surface of the solar cell connector is formed by particles of a component of the non-eutectic solder material.

The roughness of the surface of the solar cell connector is defined by means of the particle size of the particles in the solder material and can be in a range of approximately 300 nm to approximately 50 nm. The roughness of the surface of the solar cell connector is such that it is greater in comparison to the wavelengths of the incident light. Thus, the surface imparts a diffuse reflection of the incident light, wherein the incident light is deflected in different directions.

Furthermore, cooling 406 of the solder material is done such that by means of a controlled cooling of the solder material, the particle size can be adjusted. For example, in an accelerated cooling, the particles have less time for growth than in a cooling, which is takes place at room temperature and the particles in the solder material accordingly have a smaller particle size than when the cooling is not accelerated. The cooling duration of the cooling 406 of the solder material can be controlled such that the particles on the surface of the solar cell connector have a minimum size of 300 nm, for example of 1 μm.

Furthermore, cooling 406 of the solder material of the solar cell connector can be accelerated by means of a retaining device, which is pressed on one or more solar cells. The solar cell connector can be fixed during the cooling by means of the retaining device such that the pressed surface of the solar cell connector can be kept low. The retaining device can be a thin rod-shaped hold-down clamp.

Further additional production and post-processing steps of the solar cells can be bypassed. Only a minor modification of the retaining device and an adjustment of the solder material is necessary.

### EXAMPLES

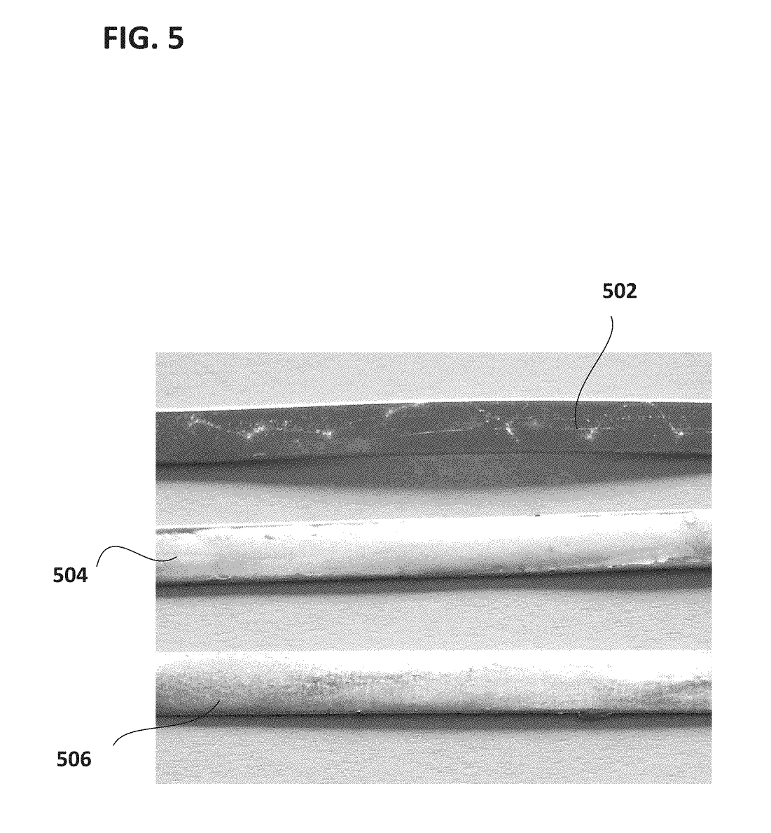

For illustrating the effects in accordance with the invention, 5 mm wide copper strips coated with a suitable solder material, were provided. The strips are coated with the ternary solder system Tin-Lead-Silver(SnPbAg). The first strip 502 has a coating with the eutectic SnPbAg solder material and was used as a reference. The weight percentage of Tin is 62% by weight, the weight percentage of Lead is 36% by weight and the weight percentage of Silver is 2% by weight. Further Tin was added to the eutectic SnPbAg solder material of a second strip, so that a strip with Tin hyper-eutectic solder material 504 was obtained. Further Lead was added to the eutectic SnPbAg solder material of a third strip, so that a cross-connector with Lead hypereutectic solder material 506 was obtained. As illustrated in FIG. 5, solidifying the Tin hyper-eutectic solder material of the strip 504 and the Lead hypereutectic solder material of the strip 506 by forming a matt whitish surface during the unmodified eutectic solder material of the strip 502 has a reflecting surface.

Pieces 602, 604, 606 of these three strips 502,504, 506 were laid between the Busbars over a solar cell and laminated.

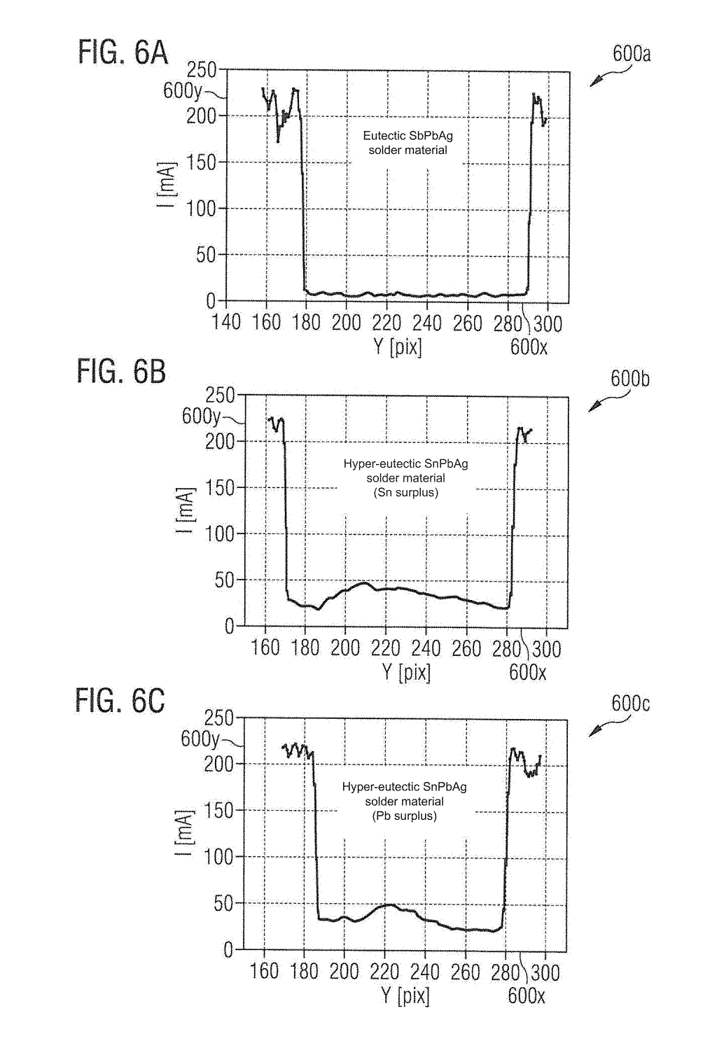

FIG. 6A shows the LBIC line scan 600a of the eutectic strip 602. Therefore, the respective scan position (in the pixel number) are represented on the x-axis 600x and the respective measured generated electric current (in mA) are represented on the y-axis 600y. From the LBIC line scan, the proportion of the captured light was determined to be 3%.

FIG. 6B shows the LBIC line scan 600b of Tin hypereutectic strip 604. Therefore, the respective scan position (in the pixel number) are represented on the x-axis 600x and the measured generated electric current (in mA) are represented on the y-axis 600y. From the LBIC line scan, the average proportion of the captured light was determined to be 14%, wherein the maximum is at 25% of the captured light.

FIG. 6C shows the LBIC line scan 600c of the Lead hyper-eutectic strip 606. Therefore, the respective scan position (in the pixel number) are represented on the x-axis 600x and the measured generated electric current (in mA) are represented on the y-axis 600y. From the 1BIC line scan, the average portion of the captured light was determined to be 11%, wherein the maximum is in a range of 23% up to 25% of the captured light.

Under ideal conditions without loss, approximately 46% light capture is expected for a complete Lambertian reflector. Since Tin-Lead solders have only about 60% reflectivity, the achievable light capture is reduced to about 27-28%, which is covered well by the captured light of up to 25% determined by means of LBIC.

With an surface percentage of the cell connector of 3.4% in the solar module, this result in a theoretical performance improvement of about 0.85%.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A photovoltaic module comprising a plurality of crystalline solar cells, which are electrically connected by solar cell connectors, the solar cell connectors comprising:
a metallic carrier; and
a non-eutectic solder material applied on the carrier, which has at least one first component and a second component;
wherein the proportion of the first or second component differs at least by 5% by weight from the eutectic point; and
wherein the solar cell connector has a diffusely reflecting rough surface.

2. The photovoltaic module of claim 1,
wherein one of the first or second component is a high-melting component.

3. The photovoltaic module of claim 1,
wherein the proportion of one of the first and second components differs by at least 20% by weight from the eutectic point.

4. The photovoltaic module of claim 1,
wherein the solder material comprises one or several more components with a proportion of up to 20% by weight of the total weight of all the components.

5. The photovoltaic module of claim 2,
wherein the first component comprises Tin, Bismuth, Lead or Indium.

6. The photovoltaic module of claim 5,
wherein the second component comprises Tin, Lead, Bismuth, Silver, Indium, Zinc or Copper.

7. The photovoltaic module of claim 2,
wherein the solder material comprises a coating thickness in a range of approximately 5 μm to approximately 100 μm.

8. The photovoltaic module of claim 7,
wherein the solder material comprises particles of a component essentially with a size of at least 300 nm.

9. The photovoltaic module of claim 8,
wherein the particles have a size in a range of 300 nm to 50 μm.

10. The photovoltaic module of claim 7,
wherein the solar cell connectors have a surface roughness of at least 150 nm.

11. The photovoltaic module of claim 1,
wherein at least 5% of the light incident perpendicular to the solar cell connector is reflected at an angle of 40° or larger.

12. A method for making a solder joint between a solar cell connector and a solar cell, the method comprising:
applying a solar cell connector on the solar cell, wherein the solar cell connector has a metallic carrier and a non-eutectic solder material applied on the carrier,
which has a first component and a second component, wherein the proportion of the first or second component differs by at least 20% by weight from the eutectic point;
heating the solder material; and
cooling the solder materials, so that an integral joint is formed between the solar cell and the solar cell connector having a rough diffusely reflecting surface.

13. The method of claim 12,
wherein one of the first or second components is a high-melting component.

14. The method of claim 12,
wherein the solder material is heated to a temperature above the liquidus temperature of this solder material.

15. The method of claim 12,
wherein the solder material is heated in a locally confined region on the solar cell connector and wherein this local region is moved along the solar cell connector with a speed between 0.1 cm/s and 10 cm/s.

16. The method of claim 12,
wherein the temperature in the local region is between 50° C. and 300° C. above the liquidus temperature of the solder material.

17. The method of claim 16,
wherein the heat input is affected by contact brazing unit, spotlight, Laser or hot air unit.

18. The method of claim 17,
wherein the rough diffusely reflecting surface is formed by the particles essentially from a component of the solder material and wherein the cooling is controlled.

19. The method of claim 18,
wherein the cooling duration is controlled such that the particles on the surface of the solar cell connector have a minimum size of approximately 300 nm.

20. The method of claim 19,
wherein during the cooling of the solder material, the solar cell connector is pressed on one or more solar cells by means of a retaining device.
